(19) United States
(12) Patent Application Publication
(10) Pub. No.: US 2014/0247849 A1
(43) Pub. Date: Sep. 4, 2014

(54) METHOD OF PRODUCING NEAR-FIELD LIGHT DEVICE, AND NEAR-FIELD LIGHT DEVICE

(71) Applicants: Takayuki Kasuya, Kanagawa (JP); Satoshi Sugiura, Kanagawa (JP); Katsumi Yoshizawa, Yamanashi (JP)

(72) Inventors: Takayuki Kasuya, Kanagawa (JP); Satoshi Sugiura, Kanagawa (JP); Katsumi Yoshizawa, Yamanashi (JP)

(73) Assignees: PIONEER CORPORATION, Kanagawa (JP); PIONEER MICRO TECHNOLOGY CORPORATION, Yamanashi (JP)

(21) Appl. No.: 14/131,015

(22) PCT Filed: Jul. 13, 2012
(86) PCT No.: PCT/JP2012/067973

§ 371 Date: May 7, 2014

(30) Foreign Application Priority Data
Jul. 15, 2011 (JP) 2011-157098
Jul. 15, 2011 (JP) 2011-157100
Jul. 15, 2011 (JP) 2011-157101

(51) Int. Cl. H01S 5/343

(52) U.S. Cl. CPC H01S 5/34313
USPC 372/45.01; 438/29

(57) ABSTRACT

A method for producing a near-field optical device is provided with: a step for forming a near-field light generation unit (10) on one surface of a transparent substrate (32); a step for forming a light source (20); and a step for adhering the transparent substrate on which the near-field light generation unit is formed, with the light source. Thereby, a method for producing a near-field optical device suited for mass production can be provided.

### TECHNICAL FIELD

The present invention relates to a near-field light device which is configured to use a nano-spot of near-field light, such as, for example, heat assisted magnetic recording (HAMR) and scanning near field optical microscope (SNOM).

### BACKGROUND ART

As an example of the use of a nanoscale light spot which uses the near-field light and which is smaller than an optical diffraction limit, for example, thermally assisted magnetic recording which uses the near-field light as a light source for increasing temperature of a magnetic recording medium (refer to Patent documents 1) is suggested.

Moreover, thanks to recent advances in semiconductor microfabrication technology, nanoscale quantum dots have drawn attention, wherein the nanoscale quantum dots use ultimate particle property by controlling a single electron with quantum mechanical effects. For example, following technologies are suggested: a production method for appropriately controlling the size of quantum dots (refer to Patent document 2), and a near-field concentrator using multi-layered quantum dots (refer to Patent document 3). Moreover, there is also suggested an approach to generate the near-field light with a vertical cavity surface emitting laser and enable high-density recording with an optical head which uses the near-field light (Non-Patent document 1).

### PRIOR ART DOCUMENT

### Patent Document

Patent document 1: Japanese Patent Application Laid Open No. 2003-045004
Patent document 2: Japanese Patent Application Laid Open No. 2009-231601
Patent document 3: Japanese Patent Application Laid Open No. 2006-080459

### Non-Patent Document

Non-Patent document 1: “Optical Near Field by Vertical Cavity Surface Emitting Laser”, The IEICE Transactions C, Vol. J83-C No. 9 pp. 826-834, September 2000

### DISCLOSURE OF INVENTION

### Subject to be Solved by the Invention

The size of a part of the near-field light device in which the near-field light is generated (hereinafter referred to as a “near-field light generating part”) is at a nano-order level, which is extremely small. Therefore, there is such a problem that it is extremely difficult to mass-produce the near-field light device in which the near-field light generating part and the light source for emitting light to the near-field light generating part are unified.

In view of the aforementioned problem, it is therefore an object of the present invention to provide a method of producing a near-field light device and the near-field light device which are suitable for the mass production.

### Means for Solving the Subject

The above object of the present invention can be solved by a method of producing a near-field light device is provided with a step of forming a near-field light generating part on one surface of a transparent substrate; a step of forming a light source; and a step of sticking the light source and the transparent substrate in which the near-field light generating part is formed.

The above object of the present invention can be solved by a near-field light device is provided with a transparent substrate; a near-field light generating part disposed on one surface of the transparent substrate; and a light source disposed on another surface of the transparent substrate.

The operation and other advantages of the present invention will become more apparent from embodiments explained below.

### BRIEF DESCRIPTION OF DRAWINGS

FIG. 1 is a diagram illustrating a structure of a near-field light device in a first embodiment.

FIG. 2 is a process cross sectional view illustrating one process of a method of producing the near-field light device in the first embodiment.

FIG. 3 is a process cross sectional view illustrating a process continued from the process in FIG. 2.

FIG. 4 is a process cross sectional view illustrating a process continued from the process in FIG. 3.

FIG. 5 is a process cross sectional view illustrating a process continued from the process in FIG. 4.

FIG. 6 is a process cross sectional view illustrating a process continued from the process in FIG. 5.

FIG. 7 is a process cross sectional view illustrating a process continued from the process in FIG. 6.

FIG. 8 is a process cross sectional view illustrating a process continued from the process in FIG. 7.

FIG. 9 is a process cross sectional view illustrating a process continued from the process in FIG. 8.

FIG. 10 is a process cross sectional view illustrating a process continued from the process in FIG. 9.

FIG. 11 is a process cross sectional view illustrating a process continued from the process in FIG. 10.

FIG. 12 is a process cross sectional view illustrating one process of a method of producing a near-field light device in a second embodiment.

FIG. 13 is a process cross sectional view illustrating a process continued from the process in FIG. 12.

FIG. 14 is a process cross sectional view illustrating a process continued from the process in FIG. 13.

FIG. 15 is a process cross sectional view illustrating a process continued from the process in FIG. 14.

FIG. 16 is a process cross sectional view illustrating a process continued from the process in FIG. 15.

FIG. 17 is a process cross sectional view illustrating a process continued from the process in FIG. 16.

FIG. 18 is a diagram illustrating a structure of a near-field light device in a first modified example of the embodiment of the present invention.

FIG. 19 is a diagram illustrating a structure of a near-field light device in a second modified example of the embodiment of the present invention.

FIG. 20 is a diagram illustrating a structure of a near-field light device in a third modified example of the embodiment of the present invention.

FIG. 21 are diagrams illustrating an example in which the near-field light device of the present invention is applied to magnetic recording.

FIG. 22 is a diagram illustrating a structure of a near-field light device in a third embodiment of the present invention.

FIG. 23 is a process cross sectional view illustrating one process of the method of producing the near-field light device in the third embodiment.

FIG. 24 is a process cross sectional view illustrating a process continued from the process in FIG. 23.

FIG. 25 is a process cross sectional view illustrating a process continued from the process in FIG. 24.

FIG. 26 is a process cross sectional view illustrating a process continued from the process in FIG. 25.

FIG. 27 is a process cross sectional view illustrating a process continued from the process in FIG. 26.

FIG. 28 is a diagram illustrating a structure of a near-field light device in a first modified example of the third embodiment of the present invention.

FIG. 29 is a diagram illustrating a structure of a near-field light device in a second modified example of the third embodiment of the present invention.

FIG. 30 is a process cross sectional view illustrating one process of a method of producing a near-field light device in a fourth embodiment.

FIG. 31 is a process cross sectional view illustrating a process continued from the process in FIG. 30.

FIG. 32 is a process cross sectional view illustrating a process continued from the process in FIG. 31.

FIG. 33 is a diagram illustrating a structure of a near-field light device in a modified example of the fourth embodiment of the present invention.

FIG. 34 are diagrams illustrating a schematic structure of a near-field light device in a fifth embodiment.

FIG. 35 is a diagram schematically illustrating a structure of a near-field light generating part in the fifth embodiment.

FIG. 36 are diagrams illustrating a schematic structure of a near-field light device in a sixth embodiment.

FIG. 37 are diagrams illustrating a schematic structure of a near-field light device in a seventh embodiment.

FIG. 38 are diagrams illustrating a schematic structure of a near-field light device in an eighth embodiment.

FIG. 39 is a diagram illustrating an example in which the near-field light device of the present invention is applied to the magnetic recording.

### MODES FOR CARRYING OUT THE INVENTION

Hereinafter, embodiments of the near-field light device of the present invention will be explained with reference to the drawings. In each of the drawings referred to below, each layer and each member have different scales so that each layer and each member have sizes large enough to be recognized on the drawing.

### First Embodiment

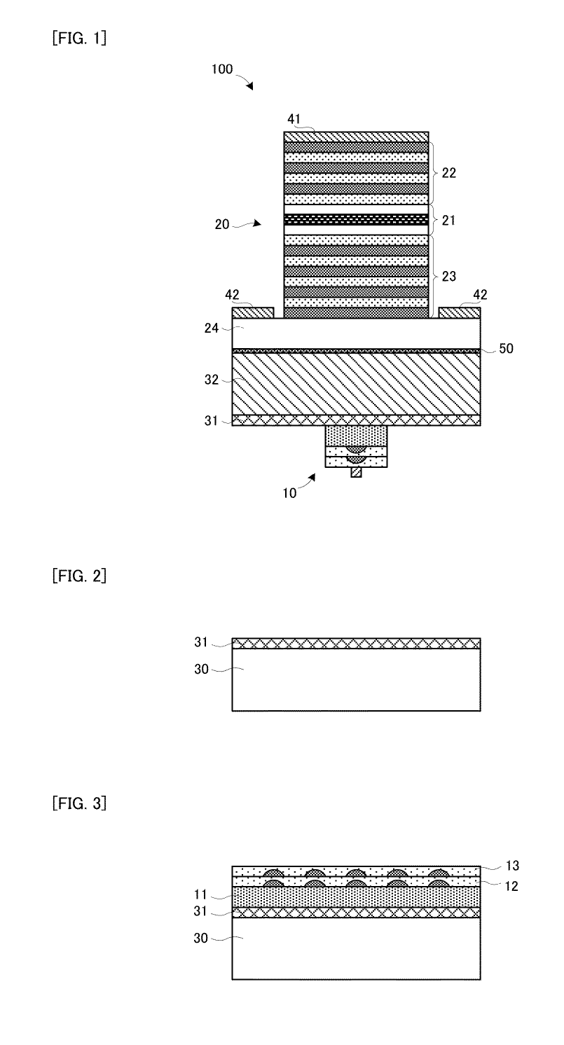

A first embodiment of the near-field light device of the present invention will be explained with reference to FIG. 1 to FIG. 11.

### (Configuration of Near-Field Light Device)

A configuration of the near-field light device in the first embodiment will be explained with reference to FIG. 1. FIG. 1 is a diagram illustrating a structure of the near-field light device in the first embodiment.

In FIG. 1, a near-field light device 100 comprises (i) a member including a glass substrate 32, a stopper layer 31 laminated on the glass substrate 32 and a near-field light generating part 10 laminated on the stopper layer 31, and (ii) a member including a n-GaAs substrate 24, a light source 20 laminated on the n-GaAs substrate 24, a first electrode 41 formed on the light source 20 and a second electrode 42 formed on the n-GaAs substrate 24. The members (i) and (ii) are bonded together with adhesive layer 50. Incidentally, the n-GaAs substrate 24 may be a p-GaAs substrate.

The light source 20 is a vertical cavity surface emitting laser (VCSEL). The configuration of the VCSEL is known to a person skilled in the art, and it is thus not described in detail herein. The light source 20 comprises an upper mirror layer 22, a active layer 21, and a lower mirror layer 23. In operation of the light source 20, electric power is supplied between the first electrode 41 and the second electrode 42.

### (Method of Producing Near-Field Light Device)

Next, a method of producing the near-field light device 100 in the first embodiment will be explained with reference to FIG. 2 to FIG. 11.

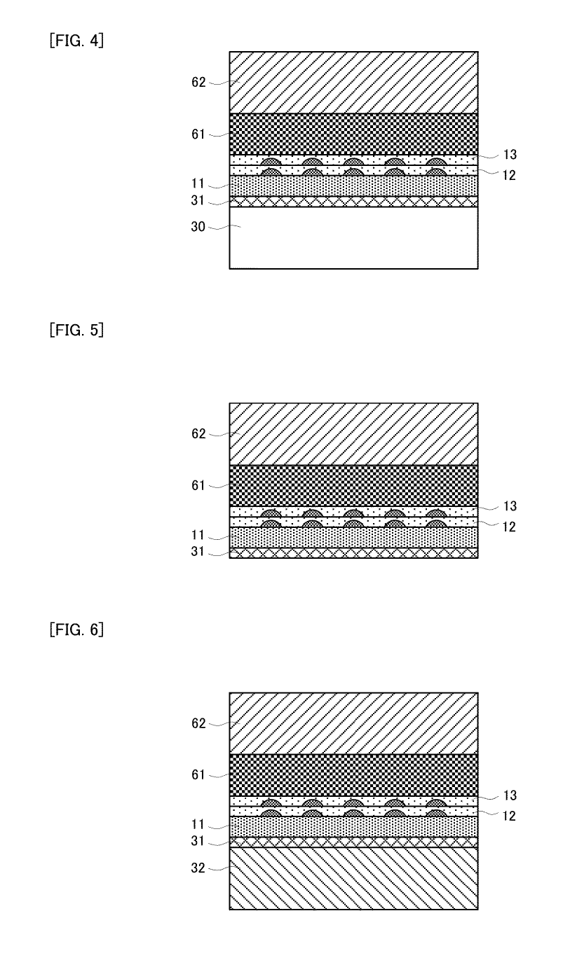

In FIG. 2, the stopper layer 31 containing, for example, GaAs is formed on a n-GaAs substrate 30. Then, as illustrated in FIG. 3, a GaAs substrate 11, a quantum dot layer 12 and a quantum dot layer 13 are laminated in this order on the stopper layer 31.

Then, as illustrated in FIG. 4, an upper surface of the quantum dot layer 13 is fixed on a silicon substrate 62, for example, by wax 61. Then, the n-GaAs substrate 30 is removed, for example, by grinding, chemical etching, or the like (refer to FIG. 5).

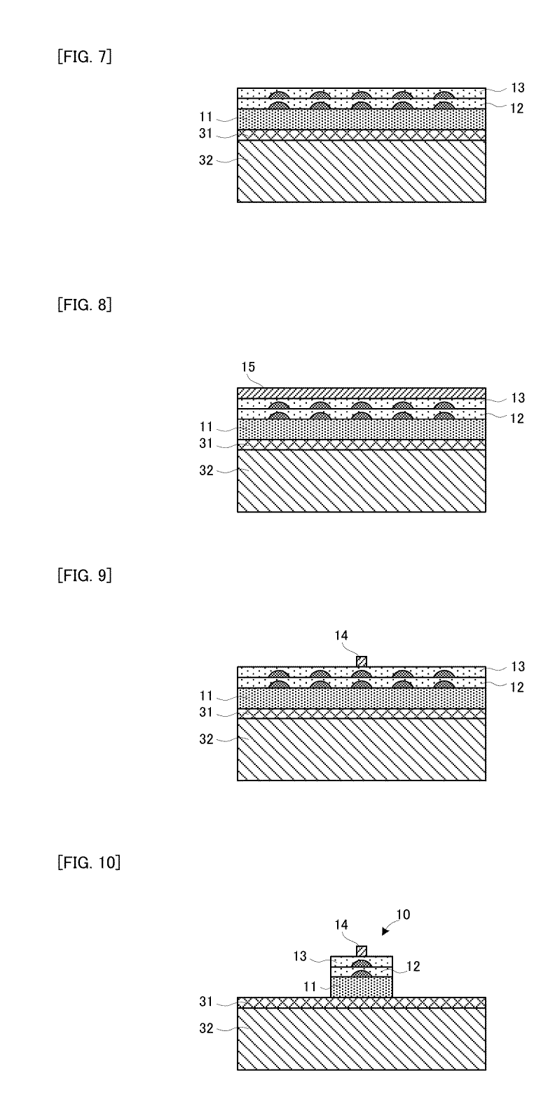

Then, as illustrated in FIG. 6, the glass substrate 32 is stuck on a lower surface of the stopper layer 31. Then, the wax 61 and the silicon substrate 62 are removed (refer to FIG. 7). Then, as illustrated in FIG. 8, a metal layer 15 containing, for example, gold (Au), copper (Cu) or the like is formed on the quantum dot layer 13.

Then, a predetermined mask is formed on the metal layer 15, and the formed mask is used to perform etching the metal layer 15. By this, a metal end 14 is formed as illustrated in FIG. 9. Then, a predetermined mask is formed on the quantum dot layer 13 is formed to cover the metal end 14, and the formed mask is used to perform etching the quantum dot layer 13, the quantum dot layer 12 and the GaAs substrate 11. By this, the near-field light generating part 10 is formed as illustrated in FIG. 10.

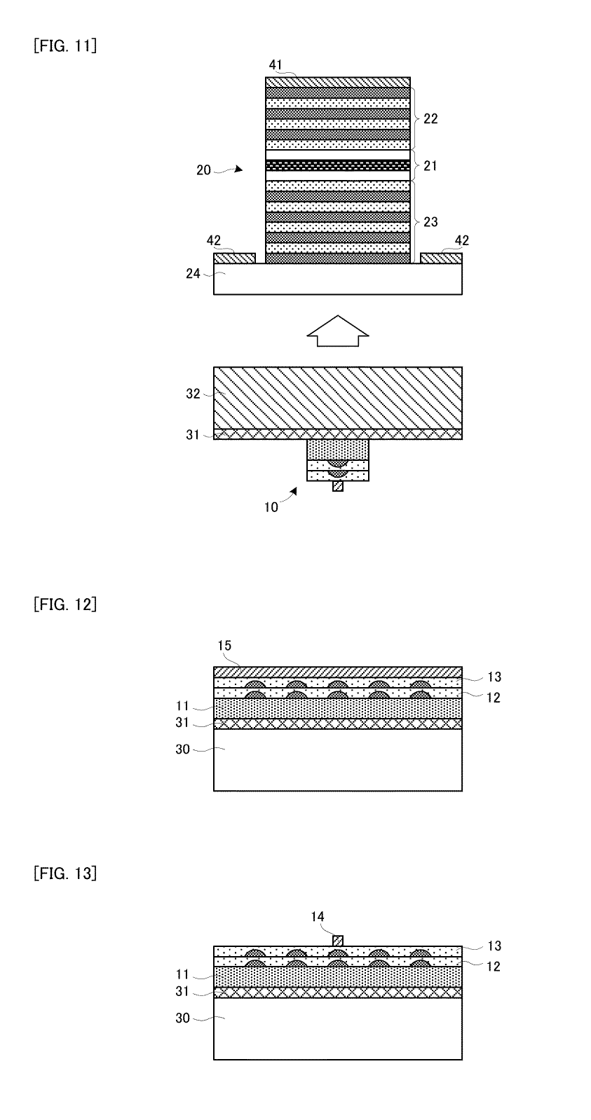

Then, as illustrated in FIG. 11, the member including the near-field light generating part 10 and the member including the light source 20 are bonded together. The member including the light source 20 is produced in a different process from a process of producing the near-field light generating part 10 illustrated in FIG. 2 to FIG. 10.

### Second Embodiment

A second embodiment of the near-field light device of the present invention will be explained with reference to FIG. 12 to FIG. 17. The second embodiment has the same configuration as that of the first embodiment, except that the method of producing the near-field light device is partially different. Thus, in the second embodiment, a duplicated explanation of the first embodiment will be omitted, and common parts have the same reference numerals on the drawings. Basically, only a different point will be explained with reference to FIG. 12 to FIG. 17.

### (Method of Producing Near-Field Light Device)

After the GaAs substrate 11, the quantum dot layer 12 and the quantum dot layer 13 are laminated in this order on the stopper layer 31 (refer to FIG. 3), the metal layer 15 is formed on the quantum dot layer 13 as illustrated in FIG. 12.

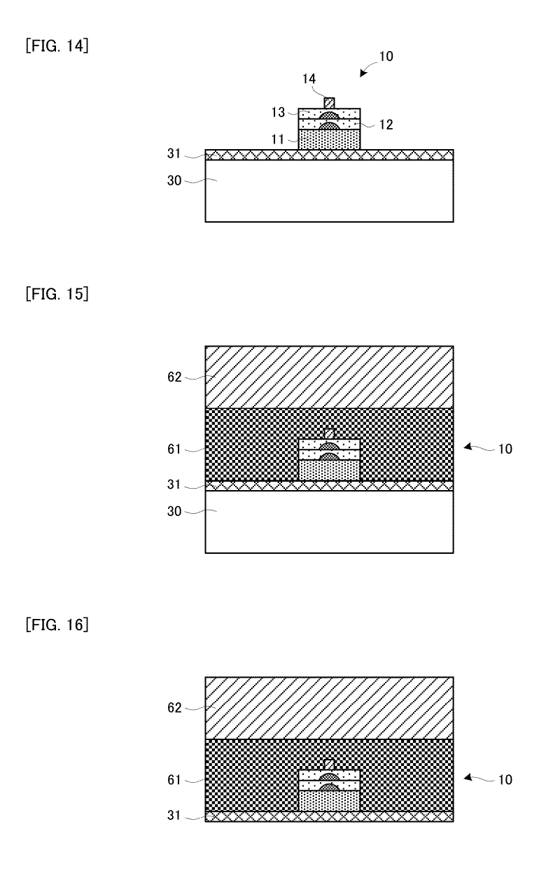

Then, a predetermined mask is formed on the metal layer 15, and the formed mask is used to perform etching the metal layer 15. By this, the metal end 14 is formed as illustrated in FIG. 13. Then, a predetermined mask for which covers the metal end 14 is formed on the quantum dot layer 13, and the formed mask is used to perform etching the quantum dot layer 13, the quantum dot layer 12 and the GaAs substrate 11. By this, the near-field light generating part 10 is formed as illustrated in FIG. 14.

Then, for example, the wax 61 or the like is applied to an upper surface of the stopper layer 31 to cover the near-field light generating part 10, and the silicon substrate 61 is laminated on the wax 61 (refer to FIG. 15). Then the n-GaAs substrate 30 is removed, for example, by grinding, chemical etching or the like (refer to FIG. 16).

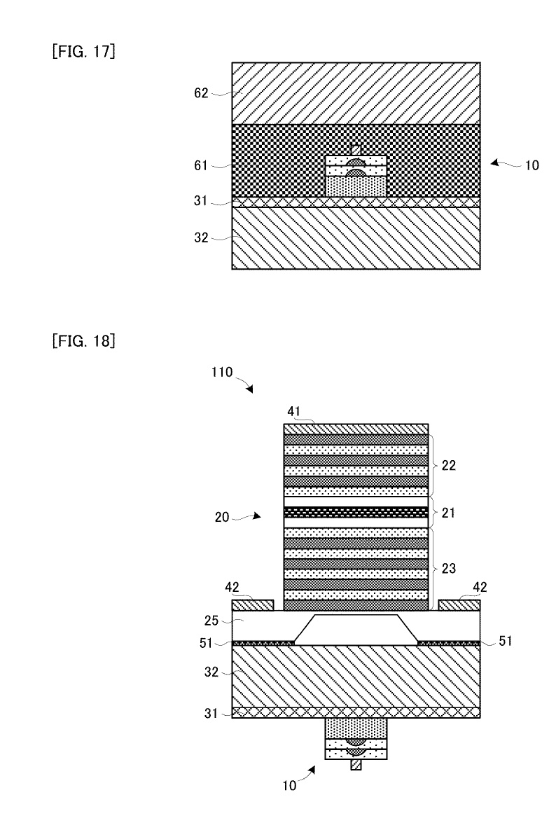

Then, as illustrated in FIG. 17, the glass substrate 32 is stuck on the lower surface of the stopper layer 31. Then, the wax 61 and the silicon substrate 62 are removed.

### MODIFIED EXAMPLES

### First Modified Example

A first modified example of the near-field light device in the embodiment of the present invention will be explained with reference to FIG. 18. FIG. 18 is a diagram illustrating a structure of a near-field light device in the first modified example of the embodiment of the present invention.

As illustrated in FIG. 18, a concave portion is formed in a one portion of a n-GaAs substrate 25 of a near-field light device 110 in the first modified example. By virtue of such a configuration, light emitted from the light source 20 can be led to the near-field light generating part 10, relatively efficiently.

### Second Modified Example

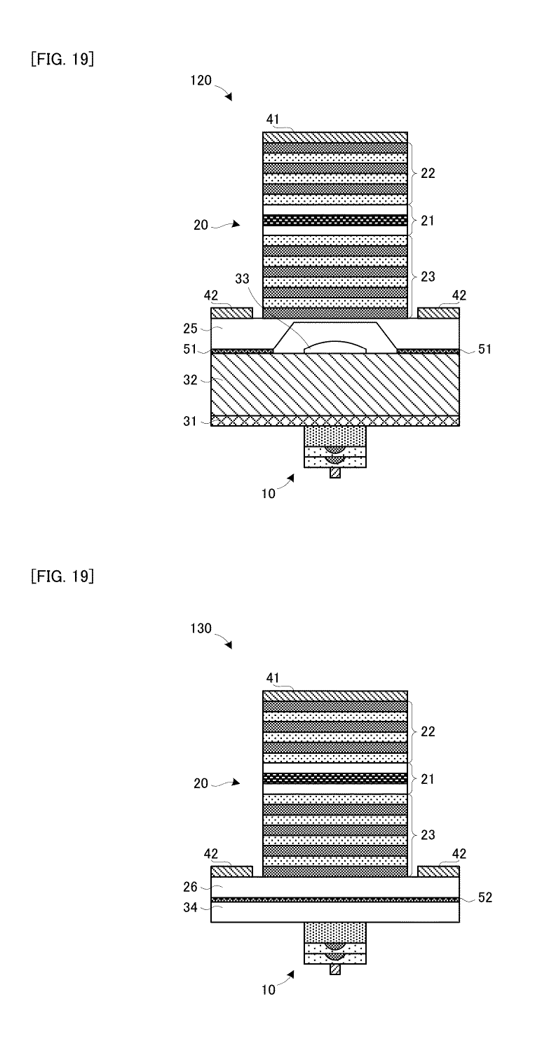

A second modified example of the near-field light device in the embodiment of the present invention will be explained with reference to FIG. 19. FIG. 19 is a diagram illustrating a structure of a near-field light device in the second modified example of the embodiment of the present invention.

As illustrated in FIG. 19, particularly in a near-field light device 120 in the second modified example, a lens 33 is formed on the glass substrate 32. By virtue of such a configuration, light emitted from the light source 20 can be focused on the near-field light generating part 10, which is extremely useful in practice. The lens 33 is not limited to a convex lens type but also may be formed by hollowing the glass substrate 32 to make a Fresnel lens in the glass substrate 32.

### Third Modified Example

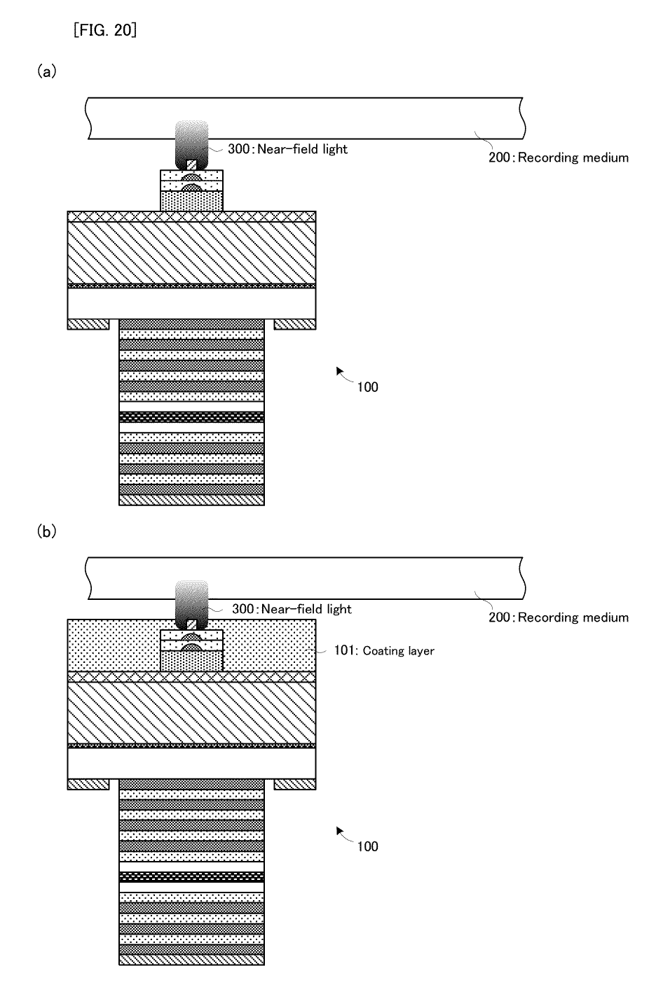

A third modified example of the near-field light device in the embodiment of the present invention will be explained with reference to FIG. 20. FIG. 20 is a diagram illustrating a structure of a near-field light device in the third modified example of the embodiment of the present invention.

As illustrated in FIG. 20, in a near-field light device 130 in the third modified example, the near-field light generating part 10 is laminated on a n-GaAs substrate 34, instead of the glass substrate. Then, the n-GaAs substrate 34 is stuck to a n-GaAs substrate 26 via an adhesive layer 52.

### APPLICATION EXAMPLE

An example in which the near-field light device of the present invention is applied to a magnetic head will be explained with reference to FIG. 21. FIGS. 21(a) and (b) are diagrams illustrating the example in which the near-field light device of the present invention is applied to magnetic recording.

FIG. 21(a) illustrates the following content. Namely, the ON/OFF of the light source 20 of the near-field light device 100 is controlled on the basis of a recording signal corresponding to information recorded on a recording medium 200, by which near-field light 300 is generated around the metal end 14 of the near-field light generating part 10 (refer to FIG. 1), and the generated near-field light 300 is eliminated. If the light source 20 is ON, energy transfers to a nano-spot of the recording medium 200 from the metal end 14 via the near-field light 300.

FIG. 21(b) illustrates a modified example of the near-field light device 100. In FIG. 21(b), the near-field light generating part 10 is covered with a coating layer 101 which is made of resins such as, for example, poly (methyl methacrylate) and a dielectric substrate such as, for example, SiO₂, to the height of an upper surface of the metal end 14. By virtue of such a configuration, it is possible to prevent that the near-field light generating part 10 is damaged. The coating layer 101 may be configured to cover not only the near-field light generating part 10 but also a surface emitting laser (or the light source 20).

If the recording medium 200 is a magnetic recording medium, energy is applied to a nano-spot of the recording medium 200, by which a coercive force of the nano-spot is reduced. Then, a magnetic field is applied by a magnetic head (not illustrated) to the nano-spot in which the coercive force is reduced, by which information recording is performed on the recording medium 200.

Incidentally, when a distance between the metal end 14 (refer to FIG. 1) of the near-field light generating part 10 and the recording medium 200 is less than or equal to a predetermined distance (e.g. less than or equal to 20 nm), the metal end 14 (refer to FIG. 1) and an area of the recording medium 200 opposed to the metal end 14 integrally generate the near-field light 300. The integrated near-field light causes heat generation in the area of the recording medium 200 opposed to the metal end 14, which improves energy use efficiency.

Moreover, if a magnetic device such as a magnetic head is formed around the near-field light device, it is necessary to match the size (or height) of the near-field light device and that of the magnetic head. In the case of the near-field light device using the VCSEL, it is possible to adjust the size (in the height direction) of the near-field light device by appropriately adjusting the thickness of the glass substrate 32.

### Third Embodiment

A third embodiment of the near-field light device of the present invention will be explained with reference to FIG. 22 to FIG. 27.

### (Configuration of Near-Field Light Device)

Firstly, a configuration of the near-field light device in the third embodiment will be explained with reference to FIG. 22. FIG. 22 is a diagram illustrating a structure of the near-field light device in the third embodiment.

In FIG. 22, a near-field light device 140 comprises a n-GaAs substrate 30, a lower electrode 44 formed on a lower surface of the n-GaAs substrate 30, a light source 20 laminated on an upper surface of the n-GaAs substrate 30, and a near-field light generating part 10 laminated on the light source 20, and an upper electrode 43 formed on an upper surface of the light source 20. Incidentally, the n-GaAs substrate 30 may be a p-GaAs substrate.

The near-field light generating part 10 comprises a GaAs substrate 11, a quantum dot layer 12 laminated on the GaAs substrate 11, a quantum dot layer 13 laminated on the quantum dot layer 12, and a metal end 14 formed on the quantum dot layer 13.

The light source 20 comprises an upper mirror layer 22, an active layer 21, and a lower mirror layer 23. In operation of the light source 20, electric power is supplied between the first electrode 43 and the second electrode 44.

### (Method of Producing Near-Field Light Device)

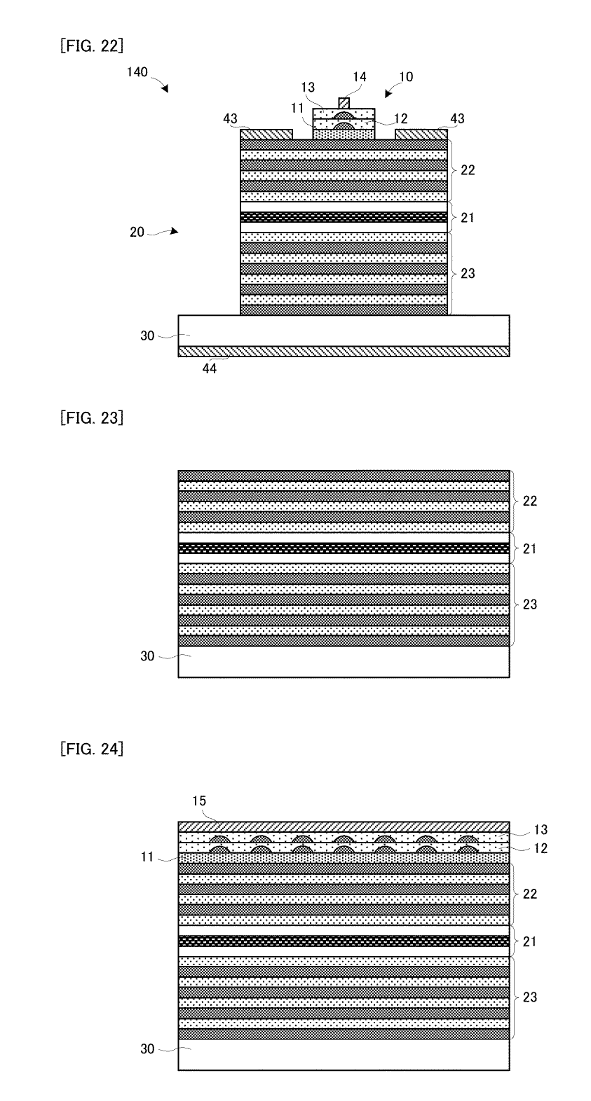

Next, a method of producing the near-field light device 140 in the third embodiment will be explained with reference to FIG. 23 to FIG. 27.

In FIG. 23, the lower mirror layer 23, the active layer 21 and the upper mirror layer 22 are laminated in this order on the n-GaAs substrate 30. Then, as illustrated in FIG. 24, the GaAs substrate 11, the quantum dot layer 12, the quantum dot layer 13 and a metal layer 15 are laminated in this order on the upper mirror layer 22.

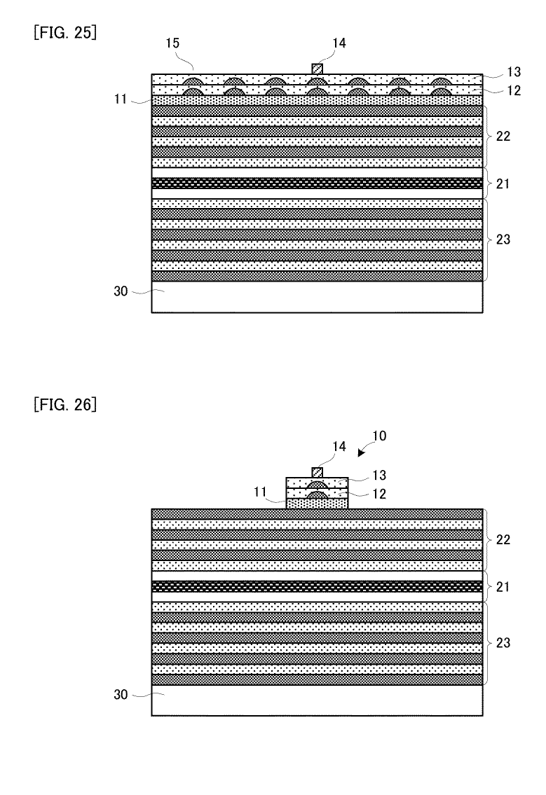

Then, a predetermined mask is formed on the metal layer 15, and the formed mask is used to perform etching or the like on the metal layer 15. By this, the metal end 14 is formed as illustrated in FIG. 25. Then, a predetermined mask for covering the metal end 14 is formed on the quantum dot layer 13, and the formed mask is used to perform etching the quantum dot layer 13, the quantum dot layer 12 and the GaAs substrate 11. By this, the near-field light generating part 10 is formed as illustrated in FIG. 26.

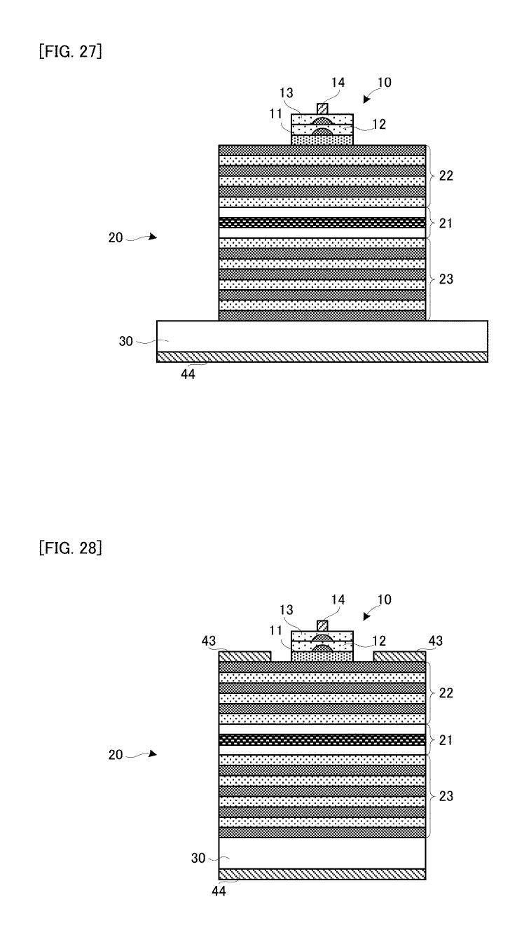

Then, a predetermined mask is formed on the upper mirror layer 22 to cover the near-field light generating part 10, and the formed mask is used to perform etching the upper mirror layer 22, the active layer 21 and the lower mirror layer 23. By this, the light source 20 is formed as illustrated in FIG. 27. Then, the upper electrode 41 is formed on the upper mirror layer 22 (refer to FIG. 1). Incidentally, the lower electrode 44 is formed typically before the process illustrated in FIG. 23. Moreover, the upper electrode 43 and the lower electrode 44 are made of, for example, gold (Au), copper (Cu) or the like.

According to the production method described above, it is possible to mass-produce the near-field light device 140 in which the near-field light generating part 10 and the light source 20 are integrally formed, relatively easily.

### MODIFIED EXAMPLES

### First Modified Example

In the process illustrated in FIG. 27, the n-GaAs substrate 30 may be also etched or the like as illustrated in FIG. 28.

### Second Modified Example

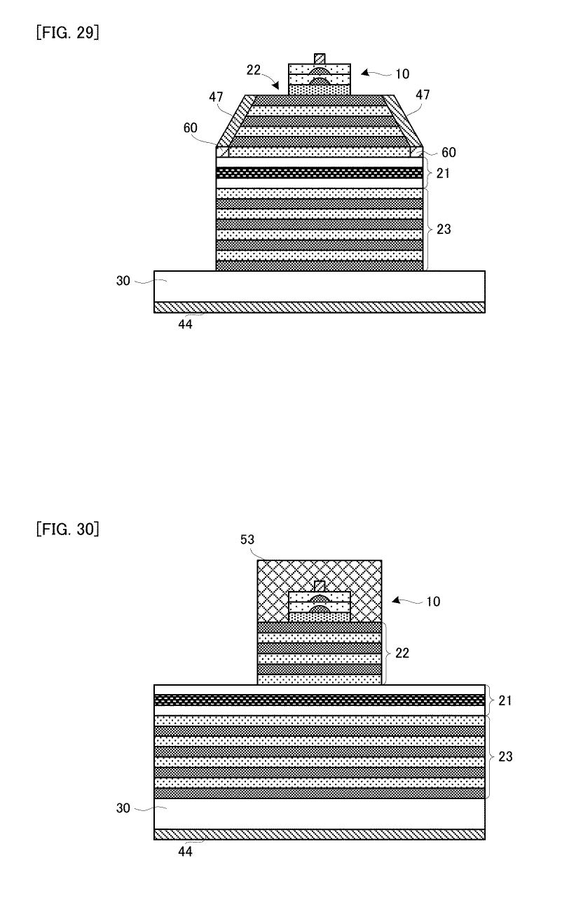

Alternatively, in the process illustrated in FIG. 27, the etching or the like may be performed to form the upper mirror layer 22 in a tapered shape as illustrated in FIG. 29. In this case, an upper electrode 47 is formed on an upper surface of the active layer 21 after the formation of an oxide film 60 made of, for example, SiO₂.

### Fourth Embodiment

A fourth embodiment of the near-field light device of the present invention will be explained with reference to FIG. 30 to FIG. 32. The fourth embodiment has the same configuration as that of the third embodiment, except that the configuration of the near-field light device is partially different. Thus, in the fourth embodiment, a duplicated explanation of the third embodiment will be omitted, and common parts have the same reference numerals on the drawings. Basically, only a different point will be explained with reference to FIG. 30 to FIG. 32.

### (Method of Producing Near-Field Light Device)

In the fourth embodiment, after the formation of the near-field light generating part 10 (FIG. 26), a predetermined mask 53 is formed on the upper mirror layer 22 to cover the near-field light generating part 10, and the formed mask 53 is used to perform etching the upper mirror layer 22. By this, the upper surface of the active layer 21 is exposed as illustrated in FIG. 30.

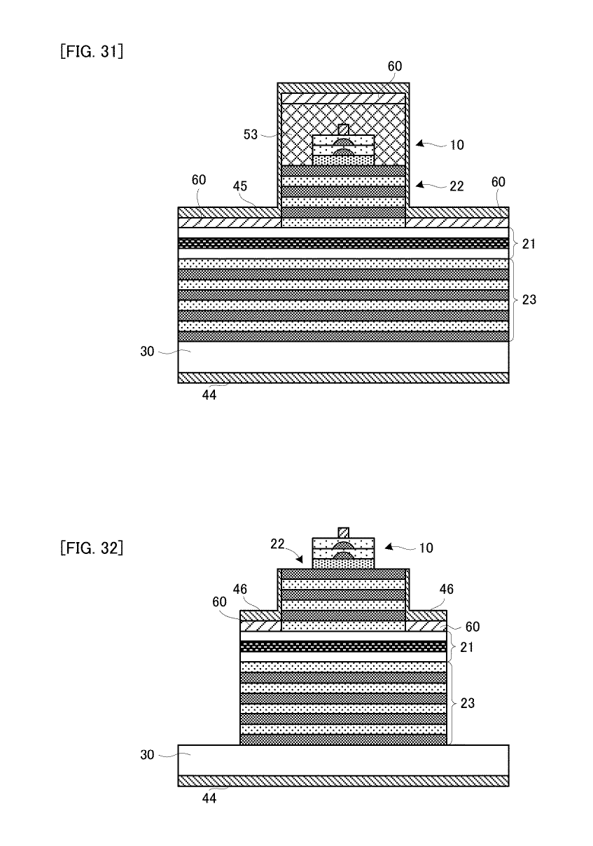

Then, the oxide film 60, for example SiO₂ or the like, is formed on the exposed upper surface of the active layer 21. Then, as illustrated in FIG. 31, a metal film 45, for example gold (Au) is formed on the formed oxide film 60.

Then, after the mask 53 is removed, a predetermined mask is used to perform etching o the metal film 45, the oxide film 60, the active layer 21 and the lower mirror layer 23. By this, an electrode 46 are formed as illustrated in FIG. 32.

### MODIFIED EXAMPLE

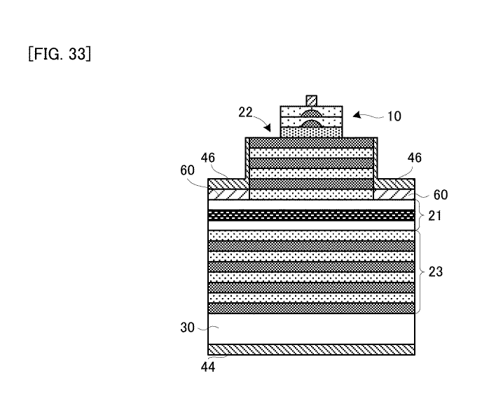

In the process illustrated in FIG. 32, the n-GaAs substrate 30 may be etched as illustrated in FIG. 33.

### Fifth Embodiment

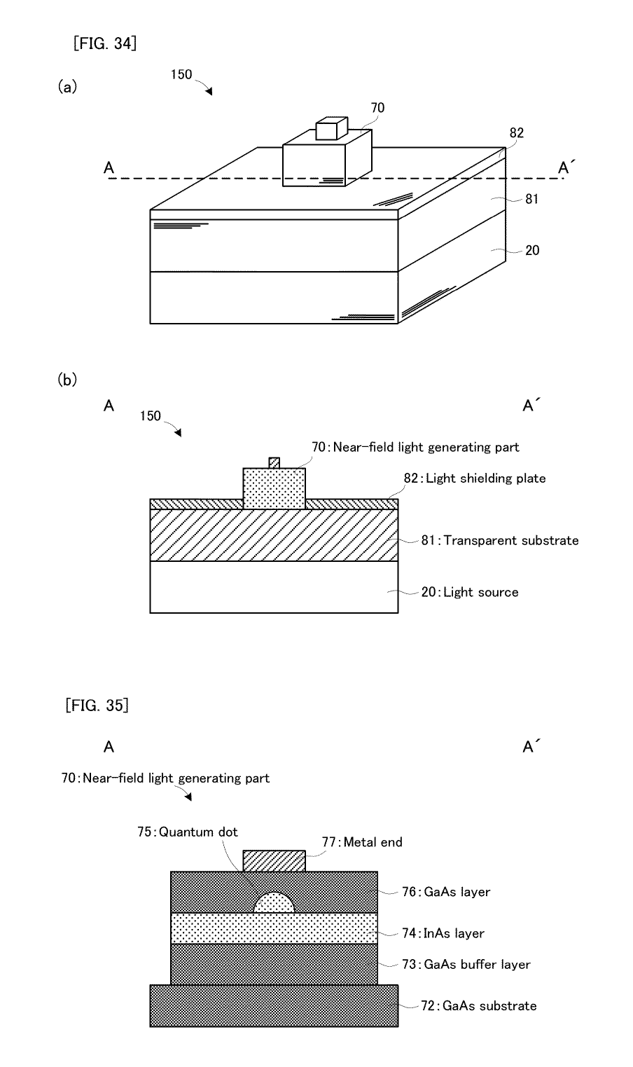

A fifth embodiment of the near-field light device of the present invention will be explained with reference to FIG. 34 and FIG. 35. FIG. 34 are diagrams illustrating a schematic structure of the near-field light device in the fifth embodiment. FIG. 34(a) is a perspective view illustrating the near-field light device in the fifth embodiment. FIG. 34(b) is a A-A′ cross sectional view of FIG. 34(a).

In FIG. 34, a near-field light device 150 comprises a light source 20, a transparent substrate 81 laminated on the light source 20, a near-field light generating part 70 laminated on the transparent substrate 81, and a light shielding plate 82 which covers the surroundings of the near-field light generating part 70 and which covers an upper surface of the transparent substrate 81.

As the light source 20, for example, a light emitting diode (LED), a semiconductor laser, a vertical cavity surface emitting laser (VCSEL), an organic electro-luminescence (EL) or the like can be applied. The transparent substrate 81 may be a substrate which is configured to transmit therethrough at least light which can appropriately operate the near-field light generating part 70, out of light emitted from the light source 20. The transparent substrate 81 is not limited to a substrate with high light transmittance, such as, for example, a glass substrate.

Now, the near-field light generating part 70 will be additionally explained with reference to FIG. 35. FIG. 35 is a diagram schematically illustrating a structure of the near-field light generating part in the fifth embodiment.

In FIG. 35, the near near-field light generating part 70 comprises a GaAs substrate 72, a GaAs buffer layer 73 laminated on the GaAs substrate 72, an InAs layer 74 laminated on the GaAs buffer layer 73, an InAs quantum dot 75 formed on the InAs layer 74, a GaAs layer 76 laminated to cover the InAs quantum dot 75, and a metal end 77 formed on the GaAs layer 76.

The metal end 77 is desirably made of a metal having an energy band in which energy of near-field light can be efficiently absorbed (e.g. gold (Au)); however, the metal end 77 may be made of a metal other than gold or a semiconductor. In the fifth embodiment, the near-field light generating part 70 is made of GaAs and InAs; however, the near-field light generating part may be made of a material having translucency or light transmitting properties, such as, for example, CuCl, GaN, and ZnO.

In operation of the near-field light device 150, the light emitted from the light source 20 is transmitted through the transparent substrate 81, the GaAs substrate 72, the GaAs buffer layer 73 and the InAs layer 74, and reaches the InAs quantum dot 75. Then, the near-field light is generated around the InAs quantum dot 75. The energy of the near-field light around the InAs quantum dot transfers to the metal end 77, which generates near-field light around the metal end 77. The energy of the near-field light around the metal end 77 transfers to a nano-spot on an object surface from the metal end 77 when a distance between the metal end 77 and an object (not illustrated) is a distance which causes a near-field interaction (e.g. 20 nanometers (nm) or less).

Here, according to the study of the present inventors, the following matter has been found; namely, the diameter of a spot formed on the upper surface of the transparent substrate 81 (a boundary surface between the transparent substrate 81 and the light shielding plate 82) by the light emitted from the light source 20 is several hundred nm to several micrometers (μm) even if the light is focused by a lens or the like. On the other hand, the size of the near-field light generating part 70 is several ten nm to several hundred nm. Therefore, light which does not enter the near-field light generating part 70 out of the light emitted from the light source 20 likely leaks out from the surroundings of the near-field light generating part 70.

In the fifth embodiment, however, the upper surface of the transparent substrate 81 is covered with the light shielding plate 82. The shielding plate 82 prevent, light emitted by the light source 20 except for entering to the near-field light generating part 70, from leaking out around the near-field light generating part 70. Metal film, a dielectric multilayer film (so-called dielectric mirror) or the like can be used for the light shielding plate 82.

### Sixth Embodiment

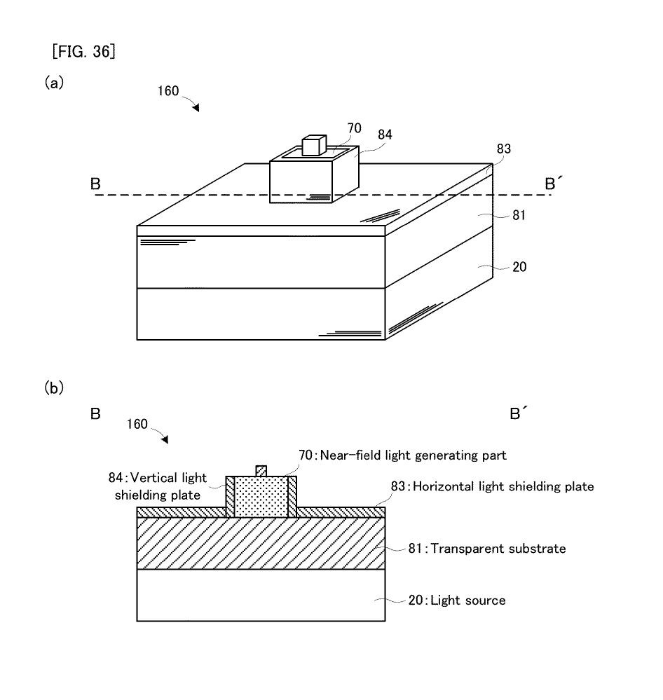

A sixth embodiment of the near-field light device of the present invention will be explained with reference to FIG. 36. The sixth embodiment has the same configuration as that of the fifth embodiment, except that the configuration of the near-field light device is partially different. Thus, in the sixth embodiment, a duplicated explanation of the fifth embodiment will be omitted, and common parts have the same reference numerals on the drawings. Basically, only a different point will be explained with reference to FIG. 36.

FIG. 36 are diagrams illustrating a schematic structure of the near-field light device in the sixth embodiment, having the same concept as that of FIG. 34. FIG. 36(a) is a perspective view illustrating the near-field light device in the sixth embodiment. FIG. 36(b) is a B-B′ cross sectional view of FIG. 36(a).

In FIG. 36, a near-field light device 160 comprises a light source 20, a transparent substrate 81 laminated on the light source 20, a near-field light generating part laminated on the transparent substrate 81, a horizontal light shielding plate 83 which surrounds the near-field light generating part 70 and which covers an upper surface of the transparent substrate 81, and a vertical light shielding plate 84 which covers a side surface of the near-field light generating part 70.

### Seventh Embodiment

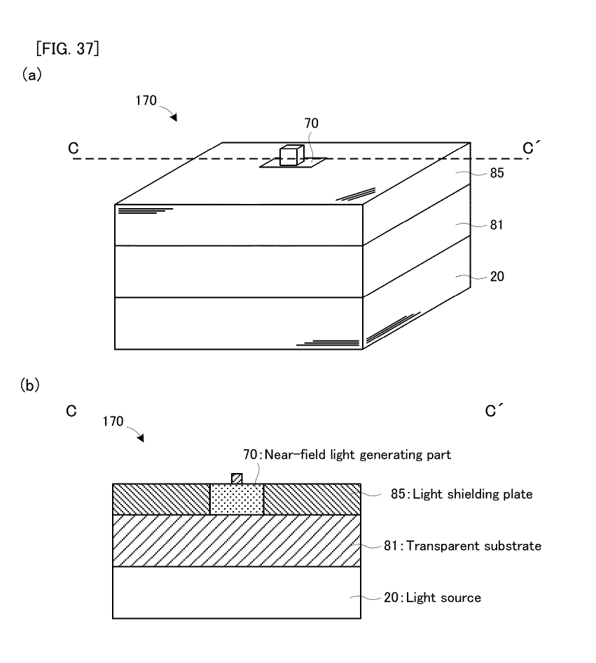

A seventh embodiment of the near-field light device of the present invention will be explained with reference to FIG. 37. The seventh embodiment has the same configuration as that of the fifth embodiment, except that the configuration of the near-field light device is partially different. Thus, in the seventh embodiment, a duplicated explanation of the fifth embodiment will be omitted, and common parts have the same reference numerals on the drawings. Basically, only a different point will be explained with reference to FIG. 37.

FIG. 37 are diagrams illustrating a schematic structure of the near-field light device in the seventh embodiment, having the same concept as that of FIG. 34. FIG. 37(a) is a perspective view illustrating the near-field light device in the sixth embodiment. FIG. 37(b) is a C-C′ cross sectional view of FIG. 37(a).

In FIG. 37, a near-field light device 170 comprises with a light source 20, a transparent substrate 81 laminated on the light source 20, a near-field light generating part laminated on the transparent substrate 81, and a light shielding plate 85 which surrounds the near-field light generating part 70 and which covers an upper surface of the transparent substrate 81.

Particularly in the seventh embodiment, the thickness of the light shielding plate 85 is equal to or almost equal to a distance between a bottom surface of a GaAs substrate 72 of the near-field light generating part 70 and an upper surface of the GaAs layer 76.

### Eighth Embodiment

An eighth embodiment of the near-field light device of the present invention will be explained with reference to FIG. 38. The eighth embodiment has the same configuration as that of the fifth embodiment, except that the configuration of the near-field light device is partially different. Thus, in the eighth embodiment, a duplicated explanation of the fifth embodiment will be omitted, and common parts have the same reference numerals on the drawings. Basically, only a different point will be explained with reference to FIG. 38.

FIG. 38 are diagrams illustrating a schematic structure of the near-field light device in the eighth embodiment, having the same concept as that of FIG. 34. FIG. 38(a) is a perspective view illustrating the near-field light device in the sixth embodiment. FIG. 38(b) is a D-D′ cross sectional view of FIG. 38(a).

In FIG. 38, a near-field light device 180 comprises a light source 20, a transparent substrate 81 laminated on the light source 20, a near-field light generating part laminated on the transparent substrate 81, and a light shielding plate 86 which surrounds the near-field light generating part 70 and which covers an upper surface of the transparent substrate 81.

Particularly in the eighth embodiment, a small groove 87 is formed between the near-field light generating part 70 and the light shielding plate 86. The groove 87 does not have to be intentionally formed, but may be unintentionally formed, for example, in the process of producing the near-field light device 180.

### APPLICATION EXAMPLE

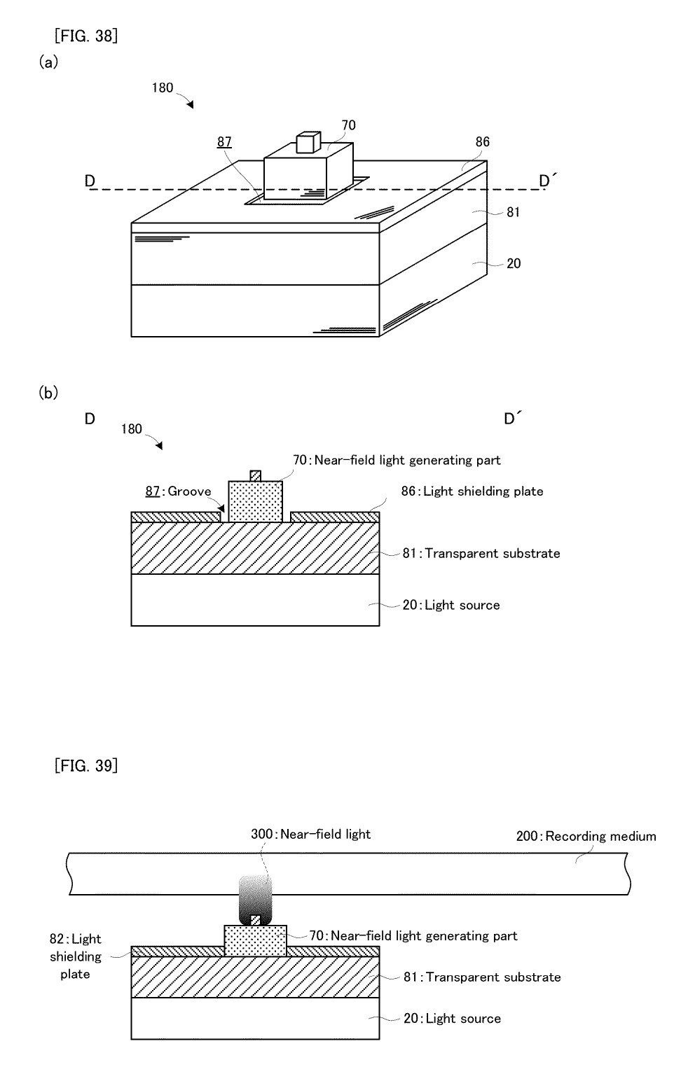

An example in which the near-field light device of the present invention is applied to a magnetic head will be explained with reference to FIG. 39. FIG. 39 is a diagram illustrating the example in which the near-field light device of the present invention is applied to the magnetic recording.

The ON/OFF of the light source 20 of the near-field light device 150 is controlled on the basis of a recording signal corresponding to information recorded on a recording medium 200, by which near-field light 300 is generated around the metal end 77 of the near-field light generating part 70 (refer to FIG. 35), and the generated near-field light 300 is eliminated. If the light source 20 is ON, energy transfers to a nano-spot of the recording medium 200 from the metal end 77 via the near-field light 300.

Energy is applied to the nano-spot of the recording medium 200, by which a coercive force of the nano-spot is reduced. Then, a magnetic field is applied by a magnetic head (not illustrated) to the nano-spot in which the coercive force is reduced, by which information recording is performed on the recording medium 200.

FIG. 39 illustrates the near-field light device 150 in the fifth embodiment described; however, the near-field light devices in the sixth to eighth embodiments can be also applied.

The present invention is not limited to the aforementioned embodiments, but various changes may be made, if desired, without departing from the essence or spirit of the invention which can be read from the claims and the entire specification. A method of producing a near-field light device and the near-field light device, which involve such changes, are also intended to be within the technical scope of the present invention.

### DESCRIPTION OF REFERENCE CODES

10, 70 near-field light generating part
20 light source
21 active layer
22 upper mirror layer
23 lower mirror layer
81 transparent substrate
82, 85, 86 light shielding plate
83 horizontal light shielding plate
84 vertical light shielding plate
100, 110, 120, 130, 140. 150, 160, 170, 180 near-field light device

1-4. (canceled)

5. A device comprising:
a light source;
a quantum dot layer which is formed on the light source; and
a metal tip which is formed on the quantum dot layer.

6. The device according to claim 5, wherein the quantum dot layer consists of an InAs layer, an InAs quantum dot and a GaAs buffer layer.

7. A device comprising:
a semiconductor substrate;
a light source which is formed on the light source and which consists of a lower mirror layer, an active layer laminated on the lower mirror layer, and an upper mirror layer laminated on the active layer;
a quantum dot layer which is formed on the upper mirror layer; and
a metal tip which is formed on the quantum dot layer.

8. The device according to claim 7, wherein a GaAs layer is formed between the upper mirror layer and the quantum dot layer.

9. A device comprising:
a semiconductor substrate;
a lower electrode which is formed on one surface of the semiconductor substrate;
a light source which is formed on other surface opposite to the one surface of the semiconductor substrate and which consists of a lower mirror layer, an active layer laminated on the lower mirror layer, and an upper mirror layer laminated on the active layer;
a quantum dot layer which is formed on the upper mirror layer;
a metal tip which is formed on the quantum dot layer; and
a upper electrode which contacts with at least a part of the upper mirror layer.

10. A method for manufacturing a device comprising:
a process of forming a light source by depositing a lower mirror layer on the semiconductor substrate, by depositing an active layer on the lower mirror layer, and by depositing an upper mirror layer on the active layer;
a process of depositing a quantum dot layer on the upper mirror layer;
a process of depositing a metal layer on the quantum dot layer; and
a process of etching the metal layer and forming a metal tip.
